(19) United States
(12) Patent Application Publication
(10) Pub. No.: US 2017/0187003 A1
(43) Pub. Date: Jun. 29, 2017

(54) ORGANIC LIGHT-EMITTING DIODE (OLED) DISPLAY PANEL AND DISPLAY APPARATUS

(71) Applicants: Shanghai Tianma AM-OLED Co., Ltd., Shanghai (CN); Tianma Micro-Electronics Co., Ltd., Shenzhen (CN)

(72) Inventors: Zhihong LEI, Shanghai (CN); Jinghua NIU, Shanghai (CN); Yuji HAMADA, Shanghai (CN); Chen LIU, Shanghai (CN); Xiangcheng WANG, Shanghai (CN); Wei HE, Shanghai (CN); Yinhe LIU, Shanghai (CN)

(21) Appl. No.: 15/459,605

(22) Filed: Mar. 15, 2017

(30) Foreign Application Priority Data
Dec. 14, 2016 (CN) 201611152979.X

(51) Int. Cl. H01L 51/52; H01L 51/50; H01L 27/32

(52) U.S. Cl. CPC H01L 51/5275; H01L 51/5234; H01L 51/5218; H01L 27/322; H01L 51/5016; H01L 51/5012; H01L 51/504; H01L 51/5072; H01L 2251/558; H01L 2251/301; H01L 2251/308; H01L 51/5056; H01L 51/0061

(57) ABSTRACT

An organic light-emitting diode (OLED) display panel and an OLED display apparatus are provided. The OLED display panel comprises: a first electrode and a second electrode disposed in a stacked configuration, wherein at least one of the first electrode and the second electrode is a light-output-side electrode; an organic luminescent layer disposed between the first electrode and the second electrode; an electron transport layer disposed between the organic luminescent layer and the second electrode; and an optical coupling layer disposed on a surface of the light-output-side electrode far away from the organic luminescent layer. The electron transport layer contains element ytterbium (Yb) with a volume percentage equal to or less than approximately 3%.

### CROSS-REFERENCES TO RELATED APPLICATIONS

This application claims priority of Chinese Patent Application No. 201611152979.X, filed on Dec. 14, 2016, the entire contents of which are hereby incorporated by reference.

### FIELD OF THE INVENTION

The present disclosure generally relates to the field of organic light-emitting diode (OLED) display technology and, more specifically, relates to an OLED display panel and an OLED display apparatus thereof.

### BACKGROUND

OLEDs have become one of the most important trends in the display industry, because of their various technological advantages, such as working without a backlight source, high contrast ratio, thin thickness, wide viewing angle and fast response. An existing OLED panel comprises a cathode, an electron transport layer, a light-emitting layer, a hole transport layer, an anode, and a substrate. In operation, a bias voltage is applied between the cathode and the anode. As a result, holes and electrons pass through the energetical barrier, and respectively migrate from the hole transport layer and the electron transport layer towards the light-emitting layer where electrons and holes further recombine to form excitons.

The formed excitons are substantially unstable, which release and transfer the energy to organic luminescent molecules in the light-emitting layer. The transferred energy leads to the energetical transition in the organic luminescent molecules from the ground state to the excited state. The light emission is consequently generated from the luminescent molecules by the spontaneous radiation decay from the excited state back to the ground state.

In an OLED display panel, the energetical barrier at the interface between the organic material and the electrode often determines the number of injected carriers, panel brightness and efficiency. However, the interface barrier between the electron transport layer and the cathode may be substantially high in the existing OLED display panels, resulting in the limited capability of electron injection and, accordingly, the poor performance of OLED display panel.

The disclosed OLED display panel and OLED display apparatus thereof are directed to solve one or more problems set forth above and other problems.

### BRIEF SUMMARY OF THE DISCLOSURE

One aspect of the present disclosure provides an OLED display panel. The OLED display panel comprises: a first electrode and a second electrode disposed in a stacked configuration, wherein at least one of the first electrode and the second electrode is a light-output-side electrode; an organic luminescent layer disposed between the first electrode and the second electrode; an electron transport layer disposed between the organic luminescent layer and the second electrode; and an optical coupling layer disposed on a surface of the light-output-side electrode far away from the organic luminescent layer. The electron transport layer contains element ytterbium (Yb) with a volume percentage equal to or less than approximately 3%.

Another aspect of the present disclosure provides an OLED display apparatus. The OLED display apparatus comprises an OLED display panel. The OLED display panel comprises: a first electrode and a second electrode disposed in a stacked configuration, wherein at least one of the first electrode and the second electrode is a light-output-side electrode; an organic luminescent layer disposed between the first electrode and the second electrode; an electron transport layer disposed between the organic luminescent layer and the second electrode; and an optical coupling layer disposed on a surface of the light-output-side electrode far away from the organic luminescent layer. The electron transport layer contains element ytterbium (Yb) with a volume percentage equal to or less than approximately 3%.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of an exemplary OLED display panel consistent with disclosed embodiments;

FIG. 2a illustrates a performance comparison between an existing OLED device and an exemplary OLED device consistent with disclosed embodiments. FIGS. 2b-d illustrate a performance comparison between an existing display panel and an exemplary OLED display panel consistent with disclosed embodiments;

FIGS. 3a-c illustrate a performance comparison of five exemplary OLED display panels consistent with disclosed embodiments;

FIG. 4a illustrates thickness-dependent refractive index of an exemplary optical coupling layer in an exemplary OLED display panel consistent with disclosed embodiments;

FIG. 4b illustrates thickness-dependent extinction coefficient of an exemplary optical coupling layer in an exemplary OLED display panel consistent with disclosed embodiments;

FIG. 5 illustrates a relationship between light transmittance of an exemplary OLED display panel and thickness of an exemplary optical coupling layer consistent with disclosed embodiments;

FIGS. 6a-b illustrate a performance comparison of four exemplary OLED display panels consistent with disclosed embodiments;

FIG. 7 illustrates a schematic diagram of another exemplary OLED display panel consistent with disclosed embodiments;

FIG. 8 illustrates a schematic diagram of another exemplary OLED display panel consistent with disclosed embodiments;

FIG. 9 illustrates a schematic diagram of another exemplary OLED display panel consistent with disclosed embodiments;

FIG. 10 illustrates a schematic diagram of another exemplary OLED display panel consistent with disclosed embodiments; and

FIG. 11 illustrates a schematic diagram of an exemplary OLED display apparatus consistent with disclosed embodiments.

### DETAILED DESCRIPTION

Reference will now be made in detail to exemplary embodiments of the invention, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all of the embodiments of the present invention. Based on the disclosed embodiments, persons of ordinary skill in the art may derive other embodiments consistent with the present disclosure, all of which are within the scope of the present invention. Further, in the present disclosure, the disclosed embodiments and the features of the disclosed embodiments may be combined under conditions without conflicts.

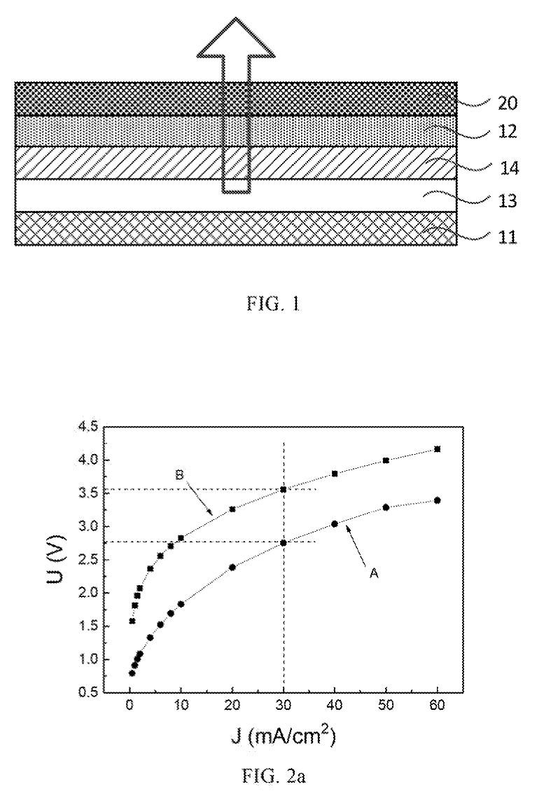

FIG. 1 illustrates a schematic structure diagram of an exemplary OLED display panel consistent with disclosed embodiments. As shown in FIG. 1, the OLED display panel may comprise a plurality of thin films disposed in a stacked configuration: a first electrode 11, a second electrode 12, an organic luminescent layer 13, an electron transport layer 14, and an optical coupling layer 20. Other appropriate components may also be included.

In particular, at least one of the first electrode 11 and the second electrode 12 may be disposed at a light output side of the OLED display panel, i.e., a side where the light is outputted from the display panel. The electrode disposed at a light output side is called as a light-output-side electrode. The organic luminescent layer 13 may be disposed between the first electrode 11 and the second electrode 12. The electron transport layer 14 may be disposed between the organic luminescent layer 13 and the second electrode 12. The electron transport layer 14 may contain an element of ytterbium (Yb) with a volume percentage equal to or less than 3%. The optical coupling layer 20 may be disposed on the surface of the light-output-side electrode far away from the organic luminescent layer 13.

In one embodiment, as shown in FIG. 1, the second electrode 12 may be disposed at the light output side, i.e., the second electrode 12 may be a light-output-side electrode, and the first electrode 11 and the second electrode 12 may be an anode and a cathode, respectively, which is for illustrative purposes and is not intended to limit the scope of the present disclosure.

According to the Fowler-Nordheim tunneling model, the element Yb in the electron transport layer 14 may reduce the interfacial energy barrier between the second electrode 12 and the electron transport layer 14. In existing OLED display panels, the electron transport layer 14 may not contain the element Yb.

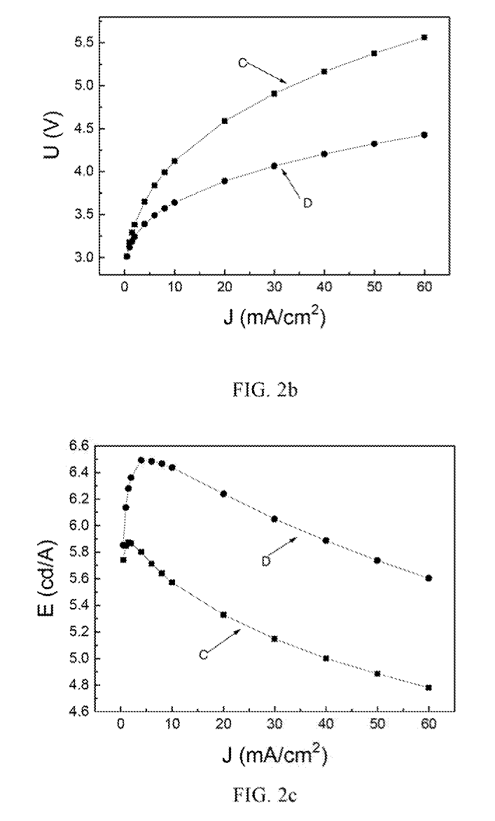

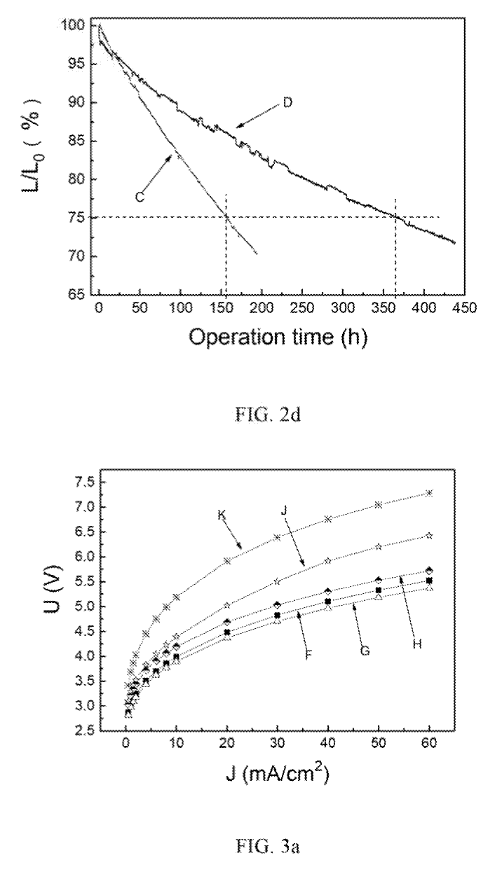

FIG. 2a illustrates a performance comparison between an existing OLED device B and an exemplary OLED device A consistent with disclosed embodiments. The OLED device A contains element Yb in the electron transport layer 14, while the OLED device B does not contain the element Yb in the electron transport layer 14.

As shown in FIG. 2a, the abscissa represents the current density, J, in the device in a unit of milliamps per square centimeter (mA/cm²), and the ordinate represents the bias voltage U, applied to the device in a unit of volts (V). Given the same current density J, the bias voltage applied to the OLED device A may be much lower than the bias voltage applied to the OLED device B, indicating that the element Yb introduced into the electron transport layer 14 may reduce the interfacial energy barrier and thus enhance the electron injection capability.

FIGS. 2b-d illustrate a performance comparison between an existing OLED display panel and an exemplary OLED display panel consistent with disclosed embodiments. As shown in FIGS. 2b-d, C represents an existing OLED display panel without the element Yb in the electron transport layer 14, and D represents a disclosed OLED display panel with the element Yb in the electron transport layer 14.

As shown in FIG. 2b, the abscissa represents the current density, J, of the OLED display panel in milliamps per square centimeter (mA/cm²), and the ordinate represents the bias voltage, U, applied to the OLED display panel in volts (V). Given the same current density J, the bias voltage U applied to the disclosed OLED display panel D may be much lower than the bias voltage applied to the existing OLED display panel C, indicating that the element Yb introduced into the electron transport layer 14 may reduce the interfacial energy barrier between the second electrode 12 (i.e., the cathode) and the electron transport layer 14, facilitate the electron injection from the second electrode 12, promote the carrier balance in the OLED display panel and, accordingly, reduce the operating voltage (i.e., the bias voltage) of the OLED display panel.

As shown in FIG. 2c, the abscissa represents the current density, J, of the OLED display panel in milliamps per square centimeter (mA/cm²), and the ordinate represents the luminous efficiency, E, of the OLED display panel in candela per ampere (cd/A). Referring to FIG. 2c, given the same current density J, the luminous efficiency E of the disclosed OLED display panel D may be much higher than the luminous efficiency E of the existing OLED display panel C, indicating that the element Yb introduced into the electron transport layer 14 may increase the luminous efficiency of the OLED display panel and, accordingly, improve the performance of the OLED display panel.

As shown in FIG. 2d, the abscissa represents the operation time of the OLED display panel in a unit of hour (h), and the ordinate represents the ratio of the OLED display panel's luminance (L) to the OLED display panel's initial luminance (L₀). Referring to FIG. 2d, the luminance of OLED display panels often decays as the operation time increases. For the disclosed OLED display panel D, after approximately 370 operation hours, the luminance may decay to 75% of the initial luminance. For the existing OLED display panel C, after approximately 160 operation hours, the luminance may decay to 75% of the initial luminance.

That is, the operation time of the disclosed OLED display panel D may be much longer than the operation time of the existing OLED display panel C, indicating that the disclosed OLED display panel D may have a longer lifetime than the existing OLED panel C. In other words, the element Yb introduced into the electron transport layer 14 may prolong the lifetime of the OLED display panel.

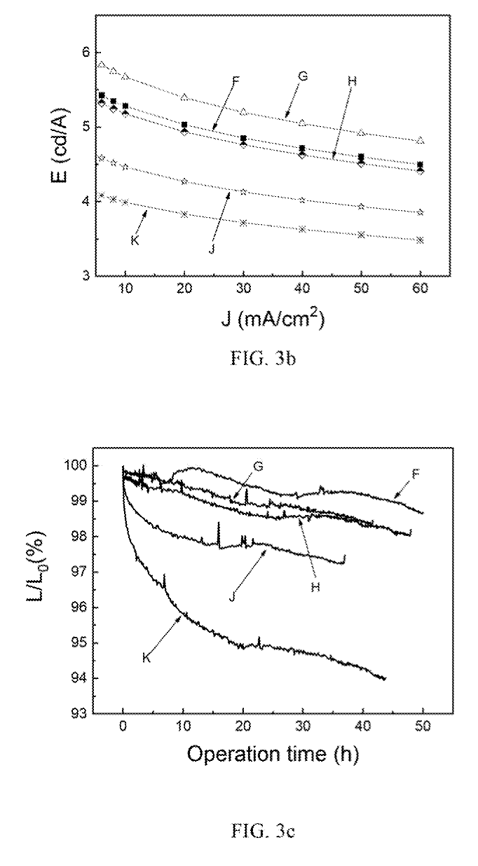

FIGS. 3a-c illustrate a performance comparison of five exemplary OLED display panels consistent with disclosed embodiments, in which each OLED display panel may be provided with a different volume percentage of element Yb in the electron transport layer 14. As shown in FIGS. 3a-c, F denotes an OLED display panel provided with a 1% volume of element Yb in the electron transport layer 14, G denotes an OLED display panel provided with a 3% volume of element Yb in the electron transport layer 14, H denotes an OLED display panel provided with a 5% volume of element Yb in the electron transport layer 14, J denotes an OLED display panel provided with a 7% volume of element Yb in the electron transport layer 14, and K denotes an OLED display panel provided with a 9% volume of element Yb in the electron transport layer 14.

As shown in FIG. 3a, the abscissa represents the current density, J, of OLED panel in milliamps per square centimeter (mA/cm²), and the ordinate represents the bias voltage, U, applied to the OLED display panel in volts (V). Referring to FIG. 3a, given the same current density J, the OLED display panels are arranged in the ascending order of the applied bias voltages U as follows: G<F<H<J<K.

As shown in FIG. 3b, the abscissa represents the current density, J, of OLED display panel in milliamps per square centimeter (mA/cm²), and the ordinate represents the luminous efficiency, E, of OLED display panel in candela per ampere (cd/A). Referring to FIG. 3b, given the same current density J, the OLED display panels are arranged in the ascending order of the luminous efficiency E as follows: K<J<H<F<G.

As shown in FIG. 3c, the abscissa represents the operation time of OLED display panel in a unit of hour (h), and the ordinate represents the ratio of the OLED display panel's luminance (L) to the OLED display panel's initial luminance (L₀). Referring to FIG. 3c, given the same ratio of L to L₀, the OLED display panels G, F and H may have significantly longer operation time than the other OLED display panels, J and K.

In summary, the OLED display panels provided with different volume percentages of element Yb in the electron transport layer 14 may differ in the performance. In practical applications, the concentration of the element Yb may be adjusted based on the various performance requirements of the OLED display panel. In one embodiment, the volume percentage of the element Yb may be configured to be equal to or less than 3% (i.e., ≦3%). According to FIGS. 3a-c, when the volume percentage of the element Yb is configured to be ≦3%, the Schottky barrier may be effectively reduced, and the electron injection capability may be improved. Thus, the carrier balance in the OLED display panel may be improved, and the performance of the OLED display panels may be enhanced, accordingly.

Returning to FIG. 1, in an operation of the OLED display panel, the light generated in the organic luminescent layer 13 may be transmitted through the light-output-side electrode (e.g., the second electrode 12). When the optical coupling layer 20 is not disposed on the light output side of the OLED display panel, the light generated in the organic luminescent layer 13, when being incident from the optically denser medium (i.e., the second electrode 12) into the optically thinner medium (i.e., air), may be reflected at the interface between the light-output-side electrode and air. Thus, the light transmittance may be decreased, i.e., the brightness of the OLED display panel may be reduced.

In the disclosed embodiments, through disposing the optical coupling layer 20 on the light output side of the OLED display panel (i.e., disposing the optical coupling layer 20 on the surface of the light-output-side electrode far away from the organic luminescent layer 13), the refractive index at the interface between the light-output-side electrode and air may be modified, the light reflection may be suppressed and, thus, the light transmittance may be improved. In other words, the brightness of the OLED display panel may be improved.

Disposing the optical coupling layer 20 on the surface of the light-output-side electrode far away from the organic luminescent layer 13 may improve the light transmittance by at least 10%. In addition, sheet resistance of the light-output-side electrode on which the optical coupling layer 20 is deposited may be reduced by at least 0.2 Ω/square.

The optical coupling layer 20 may include various materials according to various application scenarios. The chemical formulas of the materials comprising the optical coupling layer 20 may be given as follows:

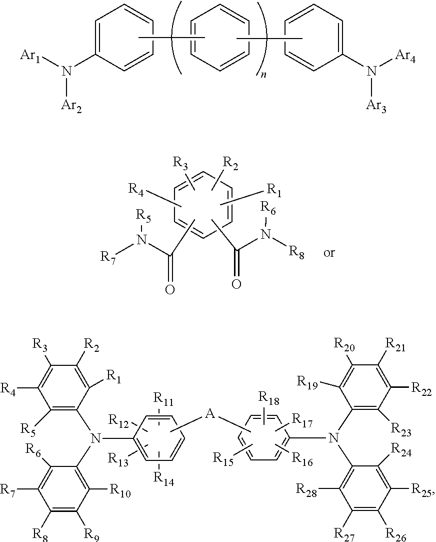

wherein Ar₂, Ar₃ and Ar₄ may be aryl groups, R₁ to R₂₈ may be alkyl groups or aryl groups, and A may be an organic group. For example, the optical coupling layer 20 may include materials with molecular formulas as follows:

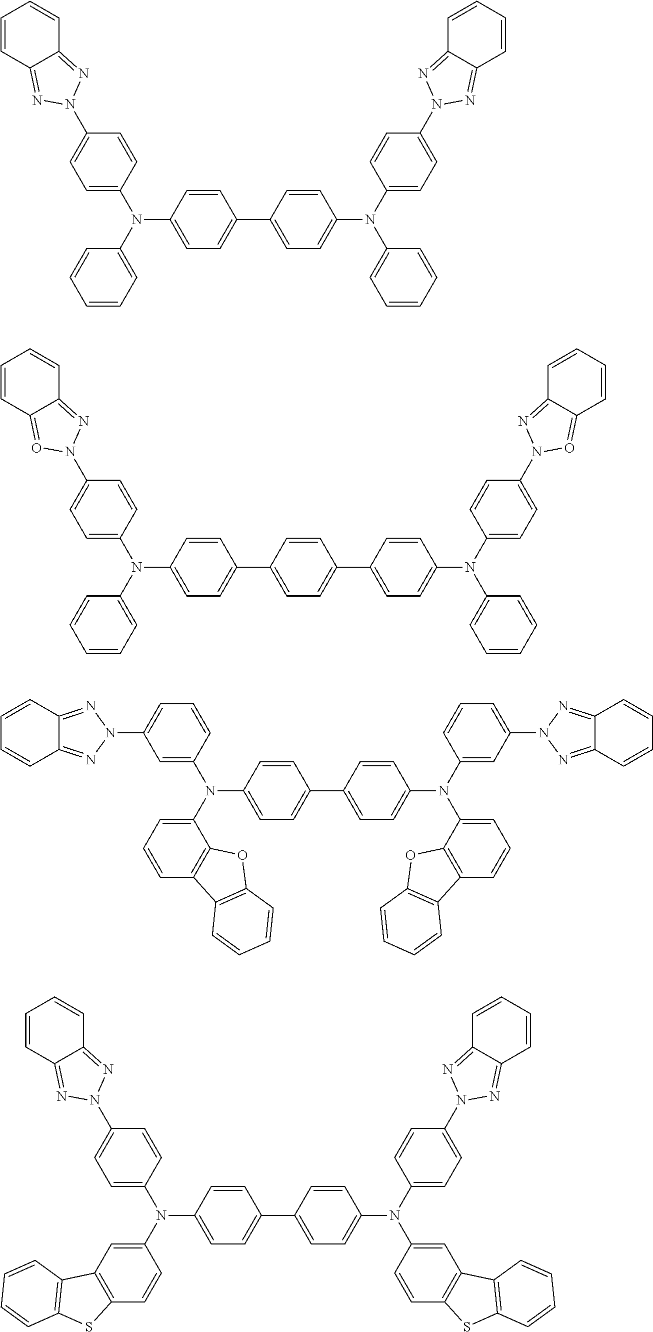

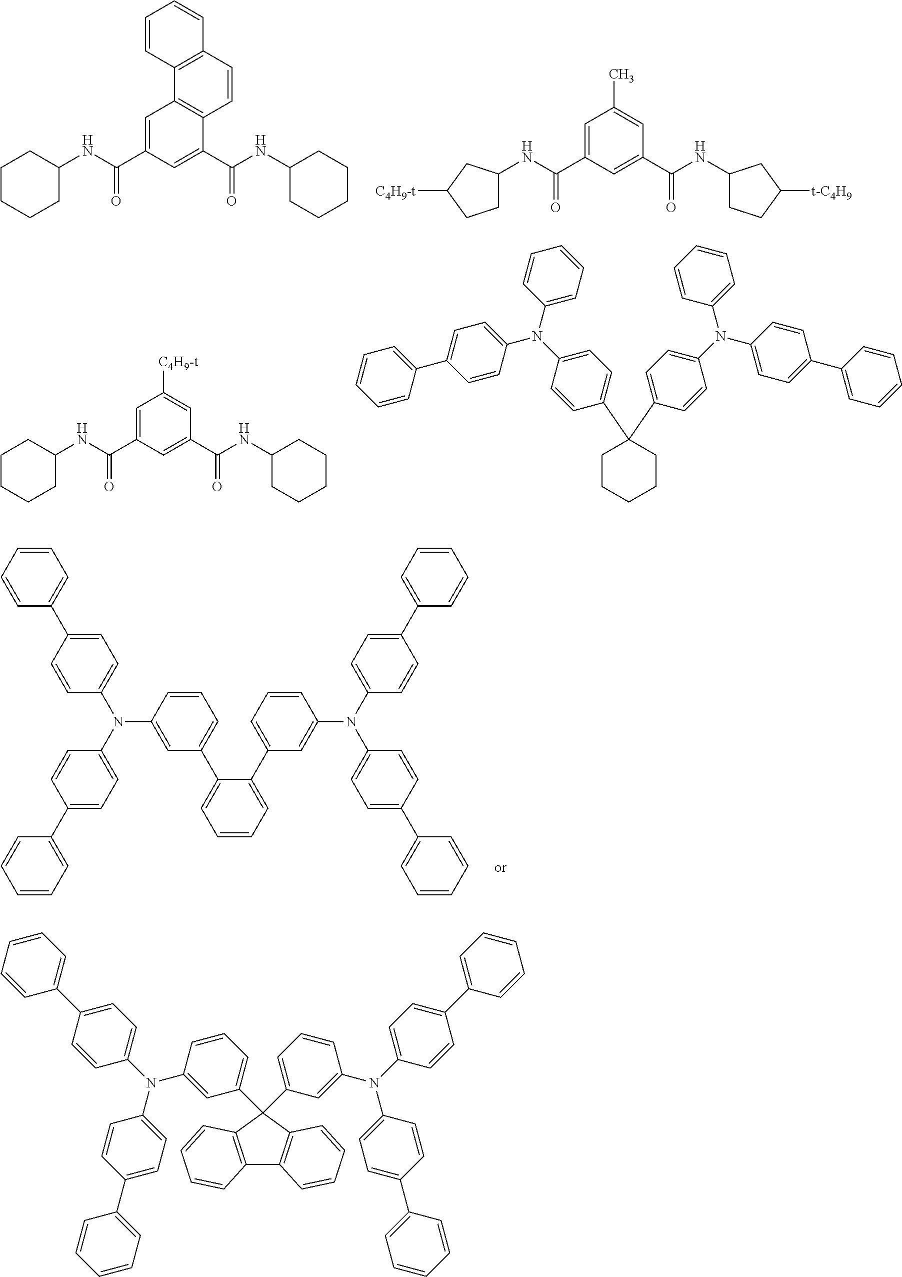

Furthermore, the thickness of the optical coupling layer 20 may vary according to various application scenarios. In practical applications, the thickness of the optical coupling layer 20 may be adjusted depending on the performance requirements of the OLED display panel.

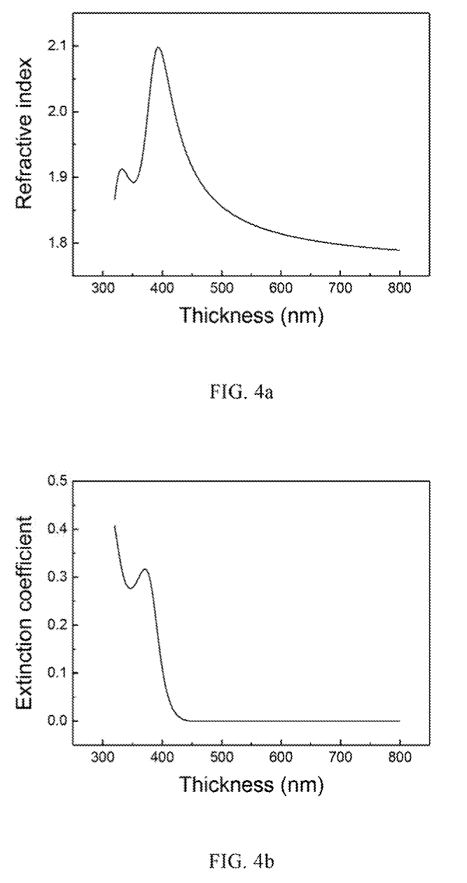

FIG. 4a illustrates thickness-dependent refractive index of an exemplary optical coupling layer in an exemplary OLED display panel consistent with disclosed embodiments. As shown in FIG. 4a, the abscissa represents the thickness of the optical coupling layer 20 in a unit of nanometer (nm), and the ordinate represents the refractive index of the optical coupling layer 20. Referring to FIG. 4a, when the thickness of the optical coupling layer 20 ranges from 500 Å to 800 Å, the refractive index of the optical coupling layer 20 may tend to be stable.

FIG. 4b illustrates thickness-dependent extinction coefficient of an exemplary optical coupling layer in an exemplary OLED display panel consistent with disclosed embodiments. As shown in FIG. 4b, the abscissa represents the thickness of the optical coupling layer 20 in a unit of nanometer (nm), and the ordinate represents the extinction coefficient of the optical coupling layer 20. The extinction coefficient may reflect the light absorption in the optical coupling layer 20. The light absorption in the optical coupling layer 20 may be increased as the extinction coefficient increases. Referring to FIG. 4b, when the thickness of the optical coupling layer 20 ranges from 500 Å to 800 Å, the extinction coefficient of the optical coupling layer 20 may tend to be stable.

Based on the results of FIGS. 4a-b, in one embodiment, the thickness of the optical coupling layer 20 may be configured to be in the range of approximately 500 Å to 800 Å. In another embodiment, the thickness of the optical coupling layer 20 may be adjusted according to various application scenarios.

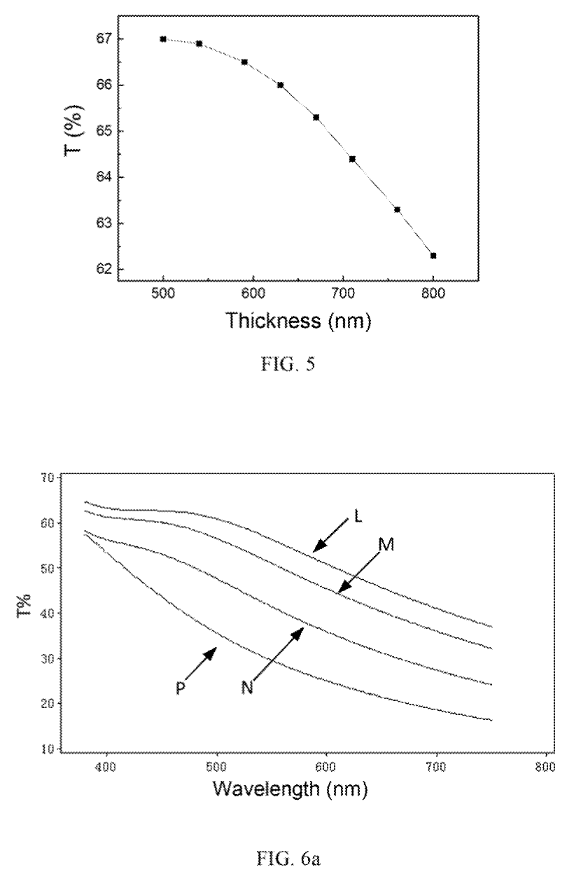

FIG. 5 illustrates a relationship between light transmittance of an exemplary OLED display panel and thickness of an exemplary optical coupling layer consistent with disclosed embodiments. As shown in FIG. 5, the abscissa represents the thickness of the optical coupling layer 20 in a unit of nanometer (nm), and the ordinate represents the light transmittance, T %, at the light output side of the OLED display panel. Referring to FIG. 5, the light transmittance T %/o may be slightly declined as the thickness of the optical coupling layer 20 gradually increases, however, the light transmittance T % may be still within an acceptable range of error. According to FIG. 5, when the thickness of the optical coupling layer 20 is in the range of approximately 500 Å to 800 Å, the OLED display panel may have a desired light transmittance.

To further enhance the image performance of the OLED display panel, in one embodiment, the light transmittance of the electrode at the light output side in the OLED display panel may be configured to be in the range of approximately 30% to 50%. The total light transmittance of the light-output-side electrode stacked with the optical coupling layer 20 may be equal to or larger than approximately 65%.

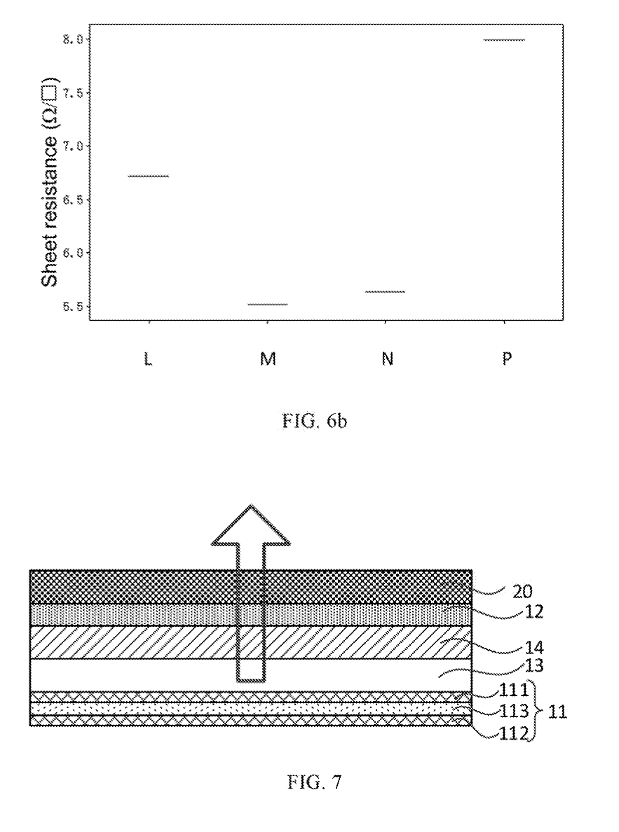

FIGS. 6a-b illustrate a performance comparison of four exemplary OLED display panels consistent with disclosed embodiments. As shown in FIGS. 6a-b, L denotes an OLED display panel including both the optical coupling layer 20 and the electron transport layer 14 with a 1% volume of element Yb, M denotes an OLED display panel including both the optical coupling layer 20 and the electron transport layer 14 with a 3% volume of element Yb, N denotes an OLED display panel including both the optical coupling layer 20 and the electron transport layer 14 with a 5% volume of element Yb, and P denotes an OLED display panel including both the optical coupling layer 20 and the electron transport layer 14 with a 10% volume of element Yb.

As shown in FIG. 6a, the abscissa represents the wavelength of the light emitted from the OLED display panel in a unit of nanometer (nm), and the ordinate represents the light transmittance, T %, at the light output side of the OLED display panel. The light transmittance may decrease to some extent as the volume percentage of element Yb in the electron transport layer 14 increases.

As shown in FIG. 6b, the abscissa represents four exemplary OLED display panels with different volume percentages of element Yb in the electron transport layer 14, and the ordinate represents the total sheet resistance of the light-output-side electrode combined with the optical coupling layer 20, in a unit of ohms per square (Ω/square). As shown in FIG. 6b, the OLED display panel M, with a 3% volume of element Yb in the electron transport layer 20, may have the smallest sheet resistance as compared to the other three OLED display panels L, N and P. That is, when the OLED display panel M is provided with a 3% volume of element Yb in the electron transport layer 20, the bias voltage applied to the OLED display panel may be reduced. Meanwhile, the sheet resistance of the disclosed OLED display panel M may be reduced by approximately 50% compared to the existing OLED display panels.

FIGS. 6a-b may further indicate that through disposing the optical coupling layer 20 at the light output side of the OLED display panel and introducing a volume percentage of element Yb equal to or less than 3% into the electron transport layer 14, the light transmittance of the OLED display panel may be effectively improved, and the operation voltage may be reduced. Accordingly, the performance of OLED display panel may be enhanced.

FIG. 7 illustrates a schematic structure diagram of another exemplary OLED display panel consistent with the disclosed embodiments. The similarities between FIG. 1 and FIG. 7 are not repeated here, while certain differences may be explained.

As shown in FIG. 7, in the disclosed OLED display panel, the second electrode may be the only light-output-side electrode, and the light generated from the organic luminescent layer 13 may emit from the stacked structure after successively passing through the electron transporting layer 14 and the second electrode 12.

Referring to FIG. 7, in particular, the first electrode 11 may include a first transparent conductive film 111, a second transparent conductive film 112, and a reflective film 113 sandwiched between the first transparent conductive film ill and the second transparent conductive film 112. The second electrode 12 may include materials of silver or sliver-based alloy.

In practical applications, the respective layers of the first electrode 11 may have various materials and thicknesses according to various application scenarios, provided that the first electrode has a desired hole injection capability and a desired light reflectivity. For example, in one embodiment, the first transparent conductive film 111 and the second transparent conductive film 112 in the first electrode 11 may be composed of indium tin oxide or indium zinc oxide, and the reflective film 113 may be composed of silver or silver-based alloy. The thickness of the reflective film 113 may range from approximately 50 nm to 150 nm.

Similarly, the thickness of the second electrode 12 may also vary according to various application scenarios, provide that the second electrode 12 has a desired electron injection capability and a desired light transmittance. For example, in one embodiment, the second electrode 12 may be composed of silver-based alloy, wherein the volume percentage of silver may be equal to or larger than approximately 80%. The thickness of the second electrode 12 may range from approximately 10 nm to 20 nm.

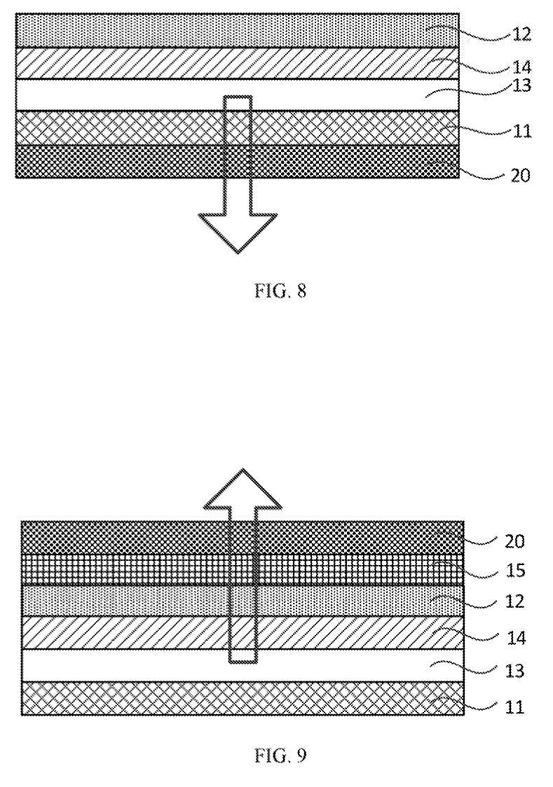

FIG. 8 illustrates a schematic structure diagram of another exemplary OLED display panel consistent with the disclosed embodiments. The similarities between FIG. 8 and FIG. 7 are not repeated here, while certain differences may be explained.

As shown in FIG. 8, only the first electrode 11 may be disposed at the light output side of the OLED display panel. That is, the first electrode 11 may be the only light-output-side electrode of the OLED display panel. The light generated by the organic luminescent layer 13 may emit after passing through the first electrode 11. In particular, the first electrode 11 may comprise transparent conductive materials, and the materials of the second electrode 12 may include silver or a silver-based alloy.

In practical design, the materials and thicknesses of the first electrode 11 may vary according to various application scenarios, provided that the first electrode has a desired hole injection capability and a desired light transmittance. For example, in one embodiment, the first electrode 11 may be composed of indium tin oxide or indium zinc oxide. Similarly, the materials and thicknesses of the second electrode 12 may also vary according to various application scenarios, provided that the second electrode 12 has a desired electron injection capability and a desired reflectivity. For example, in one embodiment, the second electrode 12 may be composed of a silver-based alloy, in which the volume percentage of silver is equal to or larger than approximately 80%, and the thickness of the second electrode may vary between approximately 50 nm and 150 nm.

Furthermore, the organic luminescent layer 13 may include organic luminescent materials for realizing white illumination. In one embodiment, the organic luminescent layer 13 may include a red light-emitting material, a green light-emitting material and a blue light-emitting material. White light emission may be obtained by mixing the lights emitted from the red, green and blue light-emitting materials.

FIG. 9 illustrates a schematic diagram of another exemplary OLED display panel consistent with disclosed embodiments. The similarities between FIG. 1 and FIG. 9 are not repeated here, while certain differences may be explained. As shown in FIG. 9, the OLED display panel may further include a color filter layer 15 disposed at the light output side of the OLED display panel, through which the white light emitted by the OLED display panel may become colored light.

When the organic luminescent layer 13 may include a red light-emitting material, a green light-emitting material and a blue light-emitting material, the red light-emitting material, the green light-emitting material and the blue light-emitting material may vary according to various application scenarios. For example, the red and the green light-emitting materials may contain phosphorescent materials. The blue light-emitting materials may contain fluorescent materials, and the fluorescent materials may include thermally activated delayed fluorescent materials. In addition, the red, the green, and the blue light-emitting materials may include host materials doped with guest materials. In particular, the red light-emitting materials may comprise one host material or two host materials, the green light-emitting materials may comprise at least two host materials, and the blue-emitting materials may comprise one host material or two host materials.

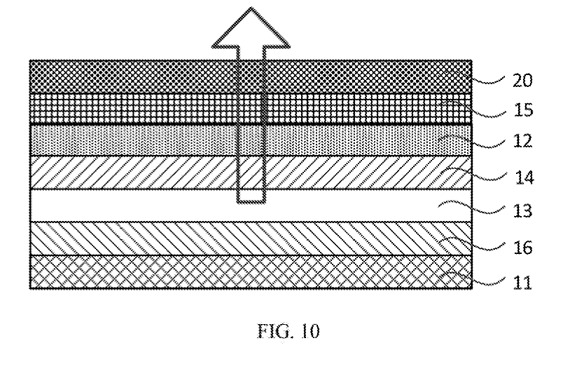

FIG. 10 illustrates a schematic diagram of another exemplary OLED display panel consistent with disclosed embodiments. The similarities between FIG. 1 and FIG. 10 are not repeated here, while certain differences may be explained. As shown in FIG. 10, the disclosed OLED display panel may further include a hole transport layer 16 disposed between the first electrode 11 and the organic luminescent layer 13.

All of the OLED display panels in the disclosed embodiments may be fabricated in various approaches according to various application scenarios. For example, in one embodiment, at the beginning the first electrode 11 may be fabricated on the substrate, then the respective layers between the first electrode 11 and the second electrode 12 may be sequentially formed, and finally the second electrode 12 may be formed. In another embodiment, the second electrode 12 may be first formed on the substrate, then the respective layers between the first electrode 11 and the second electrode 12 may be sequentially formed, and finally the first electrode 11 may be formed.

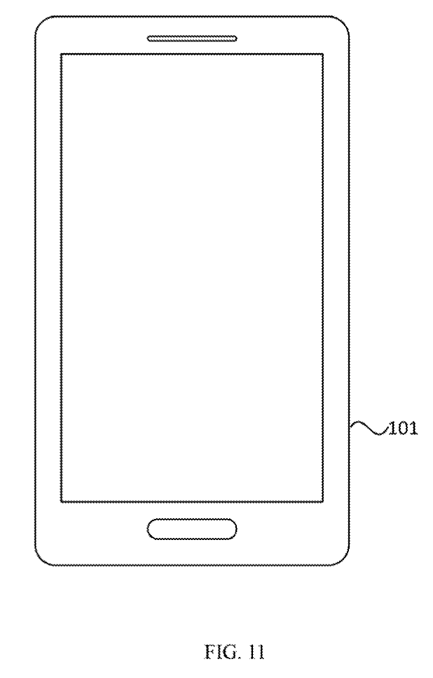

The present disclosure also provides an OLED display apparatus. FIG. 11 illustrates a schematic diagram of an exemplary OLED display apparatus 101 consistent with the disclosed embodiments. Referring to FIG. 11, the OLED display apparatus 101 may comprise any one of the OLED display panels in disclosed embodiments. For example, the disclosed OLED display apparatus 101 may be a mobile phone, a notebook computer, a smart wearable device, and an information inquiry machine in public hall, etc. Furthermore, the OLED display apparatus 101 may be any appropriate type of content-presentation devices including any of the disclosed OLED display panels. The disclosed OLED display apparatus 101 may also exhibit the same advantages as the disclosed OLED display panels.

Through introducing the element Yb with a volume percentage equal to or less than 3% into the electron transport layer 14, the disclosed OLED display panels and the OLED display apparatus may solve the problems of the substantially high energy barrier at the interface between the cathode and the electron transport layer 14 as well as the poor display performance. That is, the disclosed OLED display panels and OLED display apparatus may be able to reduce the substantially high energy barrier at the interface between the cathode and the electron transport layer 14, improve the electron injection capability and, accordingly, enhance the display performance.

Moreover, through introducing the optical coupling layer 20 into the disclosed OLED display panels, the light transmittance of the OLED display panels may be effectively improved and, accordingly, the performance of the OLED display panels may be further improved.

The description of the disclosed embodiments is provided to illustrate the present invention to those skilled in the art. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An organic light-emitting diode (OLED) display panel, comprising:
a first electrode and a second electrode disposed in a stacked configuration, wherein at least one of the first electrode and the second electrode is a light-output-side electrode;
an organic luminescent layer disposed between the first electrode and the second electrode;
an electron transport layer disposed between the organic luminescent layer and the second electrode; and
an optical coupling layer disposed on a surface of the light-output-side electrode far away from the organic luminescent layer,
wherein the electron transport layer contains element ytterbium (Yb) with a volume percentage equal to or less than approximately 3%.

2. The OLED display panel according to claim 1, wherein the optical coupling layer includes materials having the following chemical formulas: 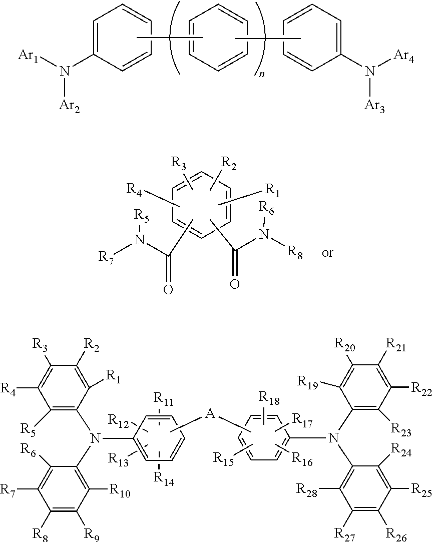
wherein Ar₂, Ar₃ and Ar₄ are aryl groups, R₁ to R₂₈ are alkyl groups or aryl groups, and A is an organic group.

3. The OLED display panel according to claim 1, wherein a thickness of the optical coupling layer approximately ranges from 500 Å to 800 Å.

4. The OLED display panel according to claim 1, wherein a light transmittance of the light-output-side electrode is approximately 30% to 50%.

5. The OLED display panel according to claim 4, wherein a total light transmittance of the optical coupling layer combined with the light-output-side electrode is equal to or larger than approximately 65%.

6. The OLED display panel according to claim 1, wherein:
the second electrode is the light-output-side electrode and includes materials of silver or a silver-based alloy; and
the first electrode comprises a first transparent conductive film, a second transparent conductive film, and a reflective film sandwiched between the first transparent conductive film and the second transparent conductive film.

7. The OLED display panel according to claim 6, wherein:
the first transparent conductive film and the second transparent conductive film comprise indium tin oxide or indium zinc oxide; and
the reflective film comprising silver or a silver-based alloy has a thickness of approximately 50 nm to 150 nm.

8. The OLED display panel according to claim 6, wherein:
the second electrode comprises a silver-based alloy;
the volume percentage of silver in the alloy is equal to or larger than approximately 80%; and
a thickness of the second electrode is approximately 10 nm to 20 nm.

9. The OLED display panel according to claim 1, wherein:
the first electrode is the light-output-side electrode, and comprises transparent conductive materials; and
the second electrode comprises silver or a silver-based alloy.

10. The OLED display panel according to claim 9 wherein:
the transparent conductive materials include indium tin oxide or indium zinc oxide.

11. The OLED display panel according to claim 9, wherein:
the second electrode comprises a silver-based alloy, wherein the volume percentage of silver is equal to or larger than approximately 80%; and
a thickness of the second electrode is approximately 50 nm to 150 nm.

12. The OLED display panel according to claim 1, wherein:
the organic luminescent layer comprises red, green and blue light-emitting materials.

13. The OLED display panel according to claim 12, wherein:
white light is obtained by mixing lights emitted from the red, green, and blue light-emitting materials.

14. The OLED display panel according to claim 13, further including:
a color filter layer disposed at the light output side, such that the white light emitted by the OLED display panel becomes colored light after passing through the color filter layer.

15. The OLED display panel according to claim 12, wherein:
the red and the green light-emitting materials include phosphorescent materials, and the blue light-emitting materials include fluorescent materials.

16. The OLED display panel according to claim 15, wherein:
the red, the green, and the blue light-emitting materials include host materials doped with guest materials; and
the red light-emitting materials comprise one host material or two host materials, the green light-emitting materials comprise at least two host materials, and the blue light-emitting materials comprise one host material or two host materials.

17. The OLED display panel according to claim 15, wherein
the fluorescent materials include thermally activated delayed fluorescent materials.

18. The OLED display panel according to claim 1, further including:
a hole transport layer disposed between the first electrode and the organic luminescent layer.

19. An organic light-emitting diode (OLED) display apparatus comprising an OLED display panel, wherein the OLED display panel comprises:
a first electrode and a second electrode disposed in a stacked configuration, wherein at least one of the first electrode and the second electrode is a light-output-side electrode;
an organic luminescent layer disposed between the first electrode and the second electrode;
an electron transport layer disposed between the organic luminescent layer and the second electrode; and
an optical coupling layer disposed on a surface of the light-output-side electrode far away from the organic luminescent layer,
wherein the electron transport layer contains element ytterbium (Yb) with a volume percentage equal to or less than approximately 3%.

20. The OLED display apparatus according to claim 19, wherein:
the optical coupling layer includes materials having the following chemical formulas: 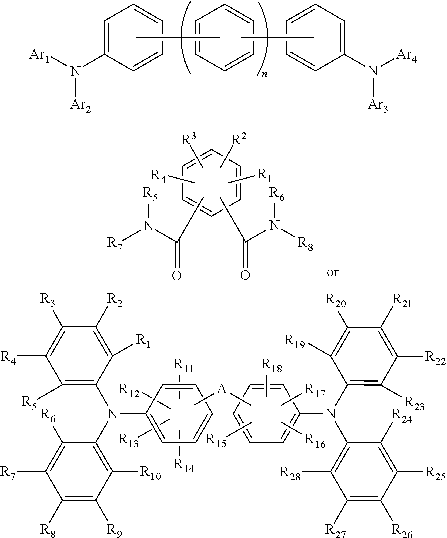
wherein Ar₂, Ar₃ and Ar₄ are aryl groups, R₁ to R₂₈ are alkyl groups or aryl groups, and A is an organic group.

21. The OLED display apparatus according to claim 19, wherein a thickness of the optical coupling layer approximately ranges from 500 Å to 800 Å.
